(19) United States
(12) Patent Application Publication
(10) Pub. No.: US 2014/0363986 A1
(43) Pub. Date: Dec. 11, 2014

(54) LASER SCANNING FOR THERMAL PROCESSING

(71) Applicant: GLOBALFOUNDRIES Inc., Grand Cayman (KY)

(72) Inventor: Jan Holub, Weisswasser (DE)

(21) Appl. No.: 13/912,761

(22) Filed: Jun. 7, 2013

(51) Int. Cl. H01L 21/67; H01L 21/268

(52) U.S. Cl. CPC H01L 21/67115; H01L 21/268
USPC 438/798; 219/121.8

(57) ABSTRACT

A system is provided for thermal processing of a semiconductor substrate including a laser configured for emitting a laser beam towards the semiconductor substrate and a scanning means configured for scanning the laser beam along a first plurality of paths on the semiconductor substrate such that the paths are spaced apart from each other by predetermined distances. Further, a method for thermal processing of a semiconductor substrate is provided including scanning a laser beam along a first plurality of paths on the semiconductor substrate such that the paths are spaced apart from each other by predetermined distances.

### BACKGROUND OF THE INVENTION

1. Field of the Invention

Generally, the present disclosure relates to the field of integrated circuits and semiconductor devices, and, more particularly, to thermal processing by laser scanning as part of the manufacturing process of integrated circuits and semiconductor devices.

2. Description of the Related Art

The fabrication of integrated circuits requires the formation of a large number of circuit elements on a given chip area according to a specified circuit layout. Generally, a plurality of process technologies are currently practiced, wherein, for complex circuitry, such as microprocessors, storage chips and the like, CMOS technology is currently one of the most promising approaches, due to the superior characteristics in view of operating speed and/or power consumption and/or cost efficiency. During the fabrication of complex integrated circuits using CMOS technology, millions of transistors, i.e., N-channel transistors and P-channel transistors, are formed on a substrate including a crystalline semiconductor layer. The fabrication includes thermal processing of intermediate (non-final) products. Thermal processing, for example, is performed for activating dopants or healing crystal defects caused by ion implantation or other invasive processing.

To give a more specific example, consider a MOS transistor, irrespective of whether an N-channel transistor or a P-channel transistor is considered, comprising so-called PN junctions that are formed by an interface of highly doped drain and source regions with an inversely doped channel region disposed between the drain region and the source region. Formation of the PN junctions includes ion implanting of dopant impurities into a wafer and annealing the wafer. The continuing shrinkage of the transistor dimensions, however, involves a plurality of issues associated therewith that have to be addressed so as to not unduly offset the advantages obtained by steadily decreasing the channel length of MOS transistors.

As transistor lateral dimensions are reduced to achieve higher speed performance and higher density of functional components on a die, the junction depths and doping profiles are also restricted to shallower locations. This scaling down of the junction depth has presently resulted in ultra-shallow junctions, having a depth of a few tens of nanometers and even less. Therefore, highly sophisticated dopant profiles, in the vertical direction as well as in the lateral direction, are required in the drain and source regions in order to provide low sheet and contact resistivity in combination with a desired channel controllability. In particular, the vertical location of the PN junctions with respect to the gate insulation layer also represents a critical design criterion in view of leakage current control, since reducing the channel length may usually also require reducing the depth of the drain and source regions with respect to the interface formed by the gate insulation layer and the channel region, thereby requiring sophisticated doping techniques. In order to have good electrical properties and a low sheet resistivity, it is important that the junction regions have a good crystalline structure with a low defect density and a high integrity. This is also crucial in order to allow subsequent selective growth processes on these regions. Moreover, for an enhanced diode function of the junction, it is desirable to have a sharp and abrupt interface between the two differently doped regions. This holds especially true for the extension regions since they are particularly sensible parts of the junction due to their low depth and close proximity to the channel region. After ion implantation, the deposited dopants are not electrically active because they are sitting in interstitial sites instead of being incorporated into the crystal lattice of the substrate material. Some regions have not been amorphized by the ion beam, but may contain a large number of defects generated by the ions. Therefore, ion implantation is typically followed by annealing, which substantially repairs the substrate damages and activates the dopants.

Other possible applications for laser anneal comprise films anneal, NiSi anneal and high-K metal gate anneal, for example.

Thermal treatment (annealing), in principle, can be performed by rapid thermal processing (RTP) using radiant lamps. However, RTP heats the entire substance (wafer), which limits ramp-up and ramp-down rates. This problem becomes more severe with increasing substrate sizes and decreasing feature sizes. Conventionally, non-pulsed CO₂ or diode lasers are used for annealing. Pulsed laser annealing uses short laser pulses for heating a surface layer only, thereby allowing for very short ramp-up and ramp-down rates than may be preferred in present day thermal treatments. For example, in the context of thermal flux laser annealing CW diode lasers produce intense beams of light that strike a wafer as a thin long line of radiation. The line of radiation is continuously scanned over the surface of the wafer in a direction perpendicular to the long dimension of the laser line beam. However, the control of the temperature of the thermally processed wafer is not satisfying. The wafer shows undesired thermal inhomogeneities. In particular, during the scanning, a newly formed stripe of anneal is affected by residual heat from an adjacent previously formed stripe. Caused by the residual heat, apparently beam wobble (at high beam powers of some 100 or 1000 W) is increased and temperature control is affected by the resulting non-uniform emission profile of the laser beam. Microuniformity of the treated surface, therefore, gets worse.

In view of the situation described above, the present disclosure provides techniques that allow for performing thermal processing of a wafer with increased uniformity, tighter laser power control and temperature control, resulting in a lower wafer breakage rate as compared to the art. The provided techniques particularly allow for reduction of the effects of varying dwell times on the standard deviation of the temperature of the thermally processed wafer. Higher wafer throughput on the wafer processing equipment as compared to the art can be archived, while maintaining good uniformity.

### SUMMARY OF THE INVENTION

The following presents a simplified summary of the invention in order to provide a basic understanding of some aspects of the invention. This summary is not an exhaustive overview of the invention. It is not intended to identify key or critical elements of the inven- tion or to delineate the scope of the invention. Its sole purpose is to present some concepts in a simplified form as a prelude to the more detailed description that is discussed later.

A system for thermal processing of a semiconductor substrate includes a laser configured for emitting a laser beam towards the semiconductor substrate and a scanning means configured for scanning the laser beam along a first plurality of paths on the semiconductor substrate such that the paths are spaced apart from each other by predetermined distances. In particular, the scanning means may include a processing unit that is configured to operate the scanning means for scanning the laser beam along a first plurality of paths on the semiconductor substrate such that the paths are spaced apart from each other by predetermined distances.

An illustrative method for thermal processing of a semiconductor substrate disclosed herein includes scanning a laser beam along a first plurality of paths on the semiconductor substrate such that the paths are spaced apart from each other by predetermined distances. The laser beam has a long dimension and strikes the semiconductor substrate as a thin long line of radiation during the scanning procedure. The thin long line of radiation might be scanned over the surface of the semiconductor substrate (wafer) in a direction substantially perpendicular to the long dimension of the beam. The paths of the first plurality of paths have widths of substantially the long dimension of the laser beam and they are spaced apart from each other in the direction of the long dimension of the laser beam.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a thermal processing system according to an illustrative embodiment;

FIG. 2 is a top view of a stage of the system illustrated in FIG. 1 holding a semiconductor substrate being thermally processed by that system;

FIG. 3 illustrates an example of a method for thermally processing a semiconductor substrate; and

FIG. 4 is a cross-sectional view of a semiconductor device during laser anneal processing performed for dopant activation.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure provides a system and a method for thermal processing of a semiconductor substrate (wafer) wherein a laser beam is scanned over the surface of the semiconductor substrate in such a manner that the scan paths of a plurality of scan paths are spaced apart from each other. The laser beam, for example, has a long dimension, say in the y-direction, and a scan path extends in the x-direction substantially perpendicular to the long dimension of the laser beam. Then, individual scan paths of the plurality of scan paths are spaced apart from each other in the y-direction. The distances between the scan paths may be constant or varying. Due to the spaced-apart formation of the scan paths, the disadvantageous effects of residual heat from a previously formed path on a subsequently formed path of the conventional thermal processing by scanned lasers are avoided. By the disclosed system and method, wafer breakage can be reduced and a higher throughput as compared to the art can be achieved.

In terms of the conventional scanning terminology, in one embodiment, the laser beam is moved during the scanning procedure perpendicular to its long dimension in a direction called the fast direction. Thereby, the laser beam is scanned from one side of the semiconductor substrate to the other to irradiate a scan path (swath) of the width of the long dimension, for example, of some mm width, on the substrate. Once the fast scan has been completed, the laser beam is moved relatively to the substrate along the long direction of the laser beam, i.e., along the so-called slow axis. Then again a fast scanning is performed to irradiate another scan path that, different from the prior art, is spaced apart from the previous scan path by some predetermined distance in the direction along the slow axis. Fast and slow scanning are repeated, possibly, in a serpentine or linear movement of the laser beam on the substrate.

The distances between individual scan paths described above may be chosen from about 0.2 to 50 times the widths of the scan paths. For example, two neighbored scan paths may be separated from each other by a distance of about 0.3 to 3 times, in particular about 1 to 2 times, a long dimension of a laser beam of a laser used for thermal processing. It is noted that, due to thermal diffusion, each scan path grows in the direction of the long dimension of the laser beam.

FIG. 1 illustrates a thermal processing system according to an illustrative embodiment. The system comprises a laser means 1, optics 2 that may include one or more lenses, a collimator and/or an expander, and a stage 3 for holding a semiconductor substrate or wafer 4 (both expressions are used interchangeable herein). The stage 3 can be any platform or chuck known in the art and adapted for securely holding the substrate during the translational movement. The stage 3 may comprise grasping means for securing the substrate, for example, suitably adapted frictional or electrical means. The grasping means may include mechanical clamps and/or electrostatic or vacuum chucks.

The laser means 1 may include diode laser modules or GaAs laser bars, for example, or any other laser element known in the art and considered suitable for a particular application. The laser means 1 may be configured for emitting radiation continuously or in the form of bursts and may emit the electromagnetic radiation with a wavelength of between 100-1000 nm, for example. The laser means 1 may be configured for emitting a laser beam with a power of at least 500 W, for example, between 50-5000 W. The laser beam emitted by the laser means 1 and shaped by the optics 2 may have a long dimension between 10-100 microns after passing the optics 2. The wavelength may be chosen according to the semiconductor substrate that is to be thermally processed.

For scanning the laser beam emitted by the laser means 1, a translational means 5 controlled by a controller 6 is provided. The translational means 5 may actuate the stage 3 or both the optics 2 and the laser means 1 or may actuate the stage 3, the optics 2 and the laser means 1 in order to cause a relative motion between the laser beam and the semiconductor substrate during the scanning process. The translational means 5 may include a conveyor, rack and pinion system or a gantry structure, each comprising drive mechanisms and may move at a constant speed of some cm/s, for example. The controller 6 controls the scan speed at which the stage 3 and the laser beam are moved relative to each other by the translational means 5. The selection of the scan speed depends on the particular application of the thermal processing (for example, dopant activation of healing of amorphous defects), the applied power density, material properties of the substrate, the long dimension of the laser beam, etc. It is noted that the translational means 5 may also be configured to adjust the height distance between the laser means 1 and the stage 3.

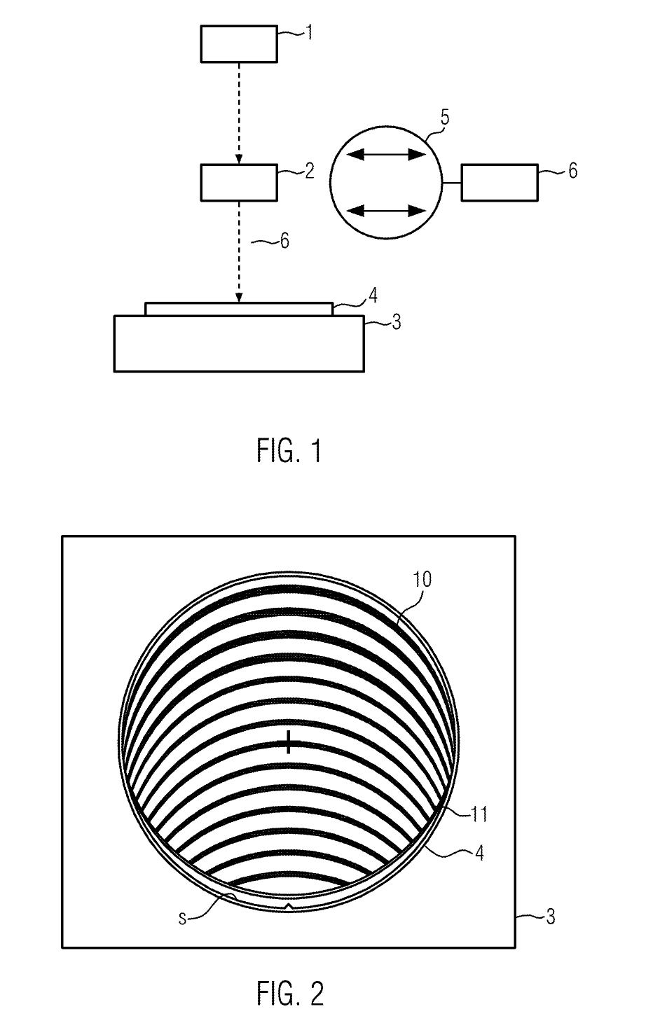

FIG. 2 shows a semiconductor substrate s on stage 3. A hot chuck is indicated by reference sign 4. The semiconductor substrate s can be a silicon substrate, in particular, a single crystal silicon substrate. Other materials may be used to form the semiconductor substrate as, for example, germanium, silicon/germanium, gallium phosphate, gallium arsenide, etc. For example, the semiconductor substrate may sit on an insulating layer as a buried oxide layer. The semiconductor substrate may be provided in the form of a silicon-on-insulator (SOI) substrate. Particularly, the semiconductor substrate may be fabricated to include active regions comprising transistors and integrated circuits (see also description below) in some intermediate processing stage. The shown substrate s is of circular shape and may have a diameter of a few hundred millimeters and a thickness of a few hundred microns.

As shown in FIG. 2, scan paths 10 of the laser beam emitted by the laser means 1 illustrated in FIG. 1 are formed on the semiconductor substrate s. The individual scan paths extend across the width of the substrate s and show widths according to the long dimension of the layer beam hitting the surface of the semiconductor substrate s (which may vary across the substrate) and are spaced apart from each other as shown in FIG. 2. The power densities of the paths may be of more than 100 kW/cm², in particular, more than 1 MW/cm², for example. For scan speeds that result in heat-up times of the substrate of below 30 ms (for heating the substrate to some 1000° C.), an almost even temperature over the major area of the substrate can be achieved. Ramp-up and ramp-down rates of some million ° C./s may result. The scanning may be performed in a serpentine manner, i.e., when a first scan path is completed the next scan path starts at the side (left or right) where the first one was completed. After the plurality of scan paths 10 shown in FIG. 2 was completed, scanning of another plurality of scan paths of laser beams over the substrate s may be performed in order to provide additional scan paths in the intermediate regions 11 between the scan paths 10 of the plurality of scan paths 10 shown in FIG. 2. Moreover, another scanning over the already formed plurality of scan paths may be performed for repeated anneal treatment if desired.

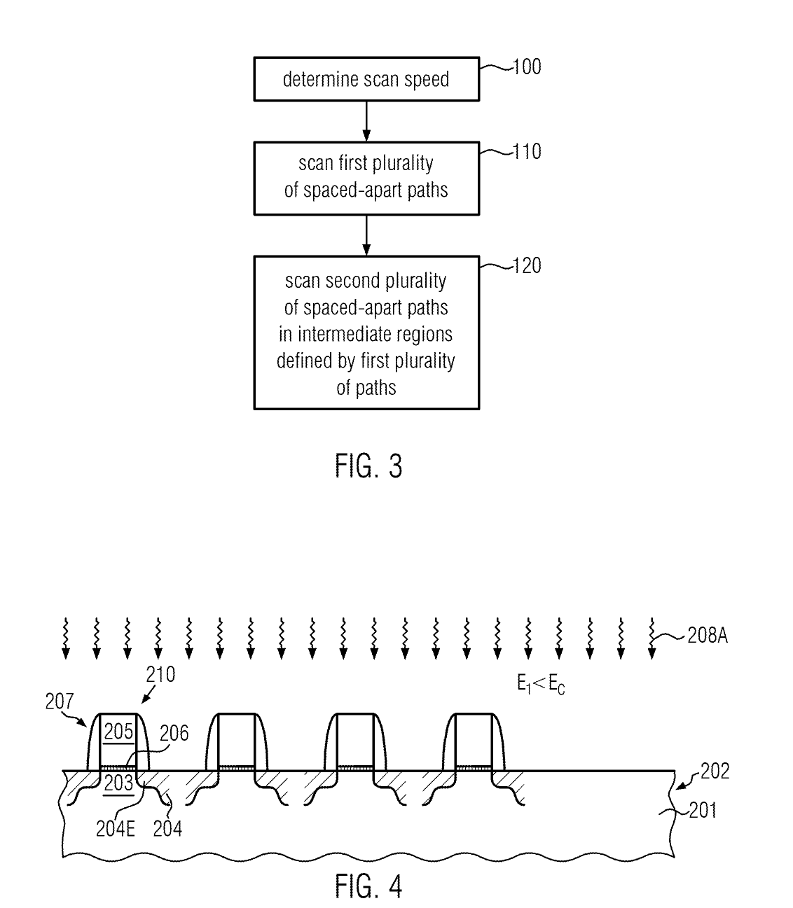

An example for a method for thermally processing a semiconductor substrate is illustrated in FIG. 3. In this method, a laser beam is scanned over a semiconductor substrate. The scan speed is determined 100 and a laser beam is scanned 110 along a first plurality of paths on the semiconductor substrate such that the paths are spaced apart from each other by predetermined distances. After the scan of the first plurality of paths on the semiconductor substrate was completed, a second plurality of scan paths of the laser beam is scanned 120 on the surface of the semiconductor substrate. The paths of the second plurality of paths are also spaced apart from each other and they are positioned in intermediate regions defined by the spaced-apart paths of the first plurality of paths. Alternatively, the second plurality of second paths is formed overlaying the first plurality of paths.

It is noted that, depending on the actual application, the dwell time, i.e., the time the area of the laser shape is exposed to the laser beam, will be controlled appropriately by the chosen scan speed. Dwell times below 1 ms are normally used. Other parameters that can be chosen according to the particular application include the laser power depending on the employed tool and beam shape, the target peak temperature and the long and short axis beam dimensions.

In the following, an example for the application of the above-described thermal processing is explained with reference to FIG. 4. The example relates to post-ion implantation annealing in the context of the formation of PN junctions for advanced transistor devices with gate lengths of at most 100 nm, in particular 50 nm or less. For such dimensions, the transistor performance is significantly determined by the overall resistance of the conductive path between the drain and source contacts. That is, in particular, the sheet resistance of the shallow drain and source extension regions, which form respective PN junctions with the adjacent channel region, play an important role in the overall transistor performance. Consequently, a high dopant concentration may typically be required, although usually somewhat lower than in the deep drain and source portions, wherein a respective dopant gradient at the PN junction may be important in view of transistor characteristics, such as switching speed and the like. Dopant activation can be achieved by the above-described thermal processing by scanned laser anneal.

FIG. 4 schematically illustrates a cross-sectional view of a semiconductor device comprising a substrate 201, which may represent any appropriate carrier material for forming thereon a semiconductor layer 202, which in turn may be comprised of any appropriate semiconductor material, such as silicon, silicon/germanium, silicon/carbon, other II-VI or III-V semiconductor compounds and the like. The semiconductor layer 202 may comprise a significant amount of silicon due to the fact that semiconductor devices of high integration density may be formed in volume production on the basis of silicon due to the enhanced availability and the well-established process techniques developed over the last decades. However, any other appropriate semiconductor materials may be used, for instance, a silicon-based material containing other iso-electronic components, such as germanium, carbon and the like. Furthermore, the substrate 201 and the semiconductor layer 202 may define an SOI configuration. In and above the semiconductor layer 202, a plurality of circuit elements 210 may be formed, wherein, in the embodiment shown, a plurality of field effect transistors may be provided. In the manufacturing stage shown, each of the transistors 210 may comprise a gate electrode 205 formed on a corresponding gate insulation layer 206, which separates the gate electrode 205 from a channel region 203 defined in the semiconductor layer 202. Moreover, a spacer structure 207 may be formed on sidewalls of the gate electrode 205. The spacer structure 207 in this manufacturing stage may comprise a plurality of individual spacer elements as required for the definition of the vertical and lateral dopant profile in respective drain and source regions, i.e., in respective deep drain and source portions 204 and respective drain and source extension regions 204E. Alternatively, one or more of the individual spacer elements of the structure 207 may have been removed after the formation of the respective drain and source regions 204, when the corresponding spacer elements are considered inappropriate for the further processing of the device.

The semiconductor device as shown in FIG. 4 may be formed on the basis of the following processes. After providing the substrate 201 including the semiconductor layer 202, respective isolation structures (not shown), such as shallow trench isolations and the like, may be formed in order to define the respective active areas for one or more of the transistor elements 210, as previously explained. For instance, the transistors 210, as shown in FIG. 4, may represent transistors of the same conductivity type, wherein some or all of the transistors 210 may be formed within the same active region. In other cases, the transistors 210 may represent transistors of different conductivity type, which may be separated by respective isolation structures (not shown). Thereafter, a corresponding doping of the one or more active regions may be performed in order to establish the required transistor base conditions, and subsequently the gate insulation layers 206 and the gate electrodes 205 may be formed on the basis of process techniques, as previously described with reference to the device 100. Next, in one illustrative embodiment, a plurality of implantation processes may be performed, for instance on the basis of respective spacer elements of the structure 207, so as to define the vertical and lateral dopant profiles of the deep drain and source portions 204 and of the extension regions 204E, wherein the respective drain and source regions for each type of transistors may be completed prior to performing a respective anneal sequence for activating dopants and re-crystallizing the damaged lattice structure.

After one or more of the implantation processes performed to define the deep drain and source portions 204 and the extension regions 204E, a laser anneal process 208A as described above is performed to activate dopants and also re-crystallize implantation-induced damage. The laser-based anneal process 208A may be performed on the basis of a process parameter setting that provides a reduced probability for creating collateral damage in sensitive device areas, such as the gate electrodes 205 and the gate insulation layers 206. An appropriate laser source may provide a continuous or a pulsed laser beam, which may be directed onto a specific device portion by means of an appropriate beam shaping system as the above-described optics. That is, depending on the output power of the laser source, the optics may provide a desired specific beam shape and thus size of a corresponding device portion and the energy density supplied thereto. An appropriate relative movement between the corresponding radiation beam and the substrate 201 is caused by the above-described translational means, wherein the corresponding scan speed may be selected so that a desired total exposure time during the anneal process 208A is obtained for each exposed device area. Since dopant diffusion may not be desirable during the laser-based anneal process 208A, the corresponding scan speed is typically selected such that an effective exposure to the radiation beam is restricted to extremely short time intervals in the range of 0.1 seconds and significantly less, such as 10 milliseconds, or even microseconds and less. On the other hand, the local temperature in the surface-near area of the substrate 201 may depend on the energy density, which is selected moderately high so as to obtain a high degree of dopant activation while not significantly contributing to dopant diffusion.

It is noted that the anneal process can be performed repeatedly. Hence, an increased degree of dopant activation may be achieved by performing a plurality of laser-based anneal processes in order to accumulate the desired effect of enhancing the degree of dopant activation during each individual step, while nevertheless maintaining the dopant diffusion in each individual step at a very low level. Each of the individual radiation-based anneal processes may be performed on the basis of less critical process parameters with respect to energy density (E₁<E_{C}) irradiated on the respective locations of the semiconductor device, thereby significantly reducing the probability for creating radiation-induced damage in each individual step and thus in the entire sequence of the plurality of radiation-based anneal processes. Therefore, in some illustrative embodiments, the radiation-based anneal process may be performed so as to expose each position on the substrate to an appropriate irradiation dose, i.e., an accumulated energy per time unit, wherein, in each time interval, critical process temperatures may be avoided, for instance in the gate electrodes, while nevertheless an efficient dopant activation may occur in the drain and source regions. Furthermore, the overall irradiation time may nevertheless be maintained sufficiently low so as to suppress or reduce any undesired diffusion activity of the dopant atoms.

It is noted that other possible applications for laser anneal comprise films anneal, NiSi anneal and high-K metal gate anneal, for example.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modi- fied and all such variations are considered within the scope and spirit of the invention. Accordingly, the protection sought herein is as set forth in the claims below.

What is claimed:

1. A system for thermal processing of a semiconductor substrate, comprising
a laser configured for emitting a laser beam towards said semiconductor substrate; and
a scanning means configured for scanning said laser beam along a first plurality of paths on said semiconductor substrate such that the paths are spaced apart from each other by predetermined distances.

2. The system of claim 1, further comprising a stage configured for holding said semiconductor substrate and wherein said scanning means comprises a translational means configured for translating said stage and said laser beam with respect to each other.

3. The system of claim 2, further comprising optical means disposed between said laser and said semiconductor substrate and configured for directing said laser beam towards said semiconductor substrate.

4. The system of claim 1, wherein said scanning means is further configured for scanning said laser beam along a second plurality of paths on said semiconductor substrate such that said second plurality of paths are spaced apart from each other by predetermined distances and disposed between or on said first plurality of paths.

5. The system of claim 1, wherein said scanning means is configured to scan said laser beam in a serpentine manner.

6. The system of claim 4, wherein said first plurality of paths are scanned in a serpentine manner.

7. The system of claim 6, wherein said second plurality of paths are scanned in a serpentine manner.

8. The system of claim 1, wherein said laser is configured for emitting said laser beam continuously or for emitting a pulsed laser beam.

9. The system of claim 1, wherein said laser is configured for emitting a laser beam with a power of at least 500 W.

10. A method for thermal processing of a semiconductor substrate, comprising
scanning a laser beam along a first plurality of paths on said semiconductor substrate such that the paths are spaced apart from each other by predetermined distances.

11. The method of claim 10, further comprising scanning said laser beam along a second plurality of paths on said semiconductor substrate such that the paths of each of said second plurality of paths are spaced apart from each other by predetermined distances and disposed between or overlying paths of said first plurality of paths.

12. The method of claim 10, wherein said laser beam is scanned in a serpentine manner.

13. The method of claim 11, wherein said first plurality of paths are scanned in a serpentine manner.

14. The method of claim 13, wherein said second plurality of paths are scanned in a serpentine manner.

15. The method of claim 10, wherein thermal processing comprises activating dopants implanted in said semiconductor substrate, manipulating dislocations present on a surface of said semiconductor substrate, crystallizing amorphous defects of said semiconductor substrate or controlling stress in one or more layers formed on said semiconductor substrate or isolation trenches formed in said semiconductor substrate.

16. The method of claim 10, wherein said semiconductor substrate is made of germanium, silicon/germanium, gallium phosphate or gallium arsenide or is an SOI substrate and wherein said semiconductor substrate includes active regions comprising transistor devices in an intermediate processing stage.
